(19) United States
(12) Patent Application Publication
(10) Pub. No.: US 2006/0286757 A1
(43) Pub. Date: Dec. 21, 2006

(54) Semiconductor product and method for forming a semiconductor product

(76) Inventors: John Power, Dresden (DE); Wolfram Langheinrich, Dresden (DE)

Correspondence Address: SLATER & MATSIL LLP, 17950 PRESTON ROAD, SUITE 1000, DALLAS, TX, 75252, US

(21) Appl. No.: 11/153,261

(22) Filed: Jun. 15, 2005

(51) Int. Cl. H01L 29/76; H01L 21/336

(52) U.S. Cl. 438/305; 257/288

(57) ABSTRACT

The invention provides a semiconductor product (25) and a method for forming the semiconductor product (25), the semiconductor product (25) comprising a transistor (1) having first (11) and second source/drain regions (12) being arranged at bottom surfaces (B) of recesses (R) in a substrate (2). Due to the depth (d) of the recesses (R) a vertical offset (29) between the source/drain regions (11, 12) and a gate dielectric (4) is achieved. The vertical offset (29) allows reducing a lateral offset (28) between the source/drain regions (11, 12) and the gate dielectric (4). Thereby, the substrate surface area required for a transistor is reduced. In particular in high voltage areas of semiconductor products like memory devices, substrate area is used more efficiently.

### TECHNICAL FIELD

The present invention relates to the field of semiconductor products comprising integrated transistors and the manufacture of integrated circuits comprising transistors. More specifically, the present invention relates to MOSFET transistors (metal oxide semiconductor field effect transistors) integrated in microelectronic circuits.

### BACKGROUND

MOSFET transistors comprise a patterned stack called a gate stack. The patterned stack comprises a gate dielectric and a gate electrode (e.g., forming part of a wordline in a memory cell). The patterned stack is provided on a main surface of a semiconductor substrate. On two opposed lateral sides of the patterned stack, source/drain regions are provided in the substrate. The source/drain regions are highly doped diffusion regions extending from the main surface of the semiconductor substrate into the inner of the substrate. The gate electrode is isolated from the substrate region between the two opposed source/drain regions (the channel region) by the gate dielectric. The gate electrode serves to control formation of a transistor channel between the two source/drain regions.

In semiconductor manufacture, the two source/drain regions are usually formed by implanting dopants into exposed regions of the main surface of the substrate. During the implantation step the patterned stack protects the channel region covered with the patterned stack from being doped with the highly concentrated dopants. The dielectric spacers covering two opposed sidewalls of the patterned stack serve to adjust the lateral distance between the respective source/drain region and the channel region.

In the manufacture of transistors to be operated at operating voltages of between about 10 and about 25 volts, for instance, LDD regions (lightly doped drain) are provided between the channel region and the area where source/drain regions are to be formed. The LDD regions serve to reduce the electrical field occurring where the LDD regions overlap the gate. The LDD regions are lightly doped diffusion regions having a dopant concentration being higher than a dopant concentration of the channel region but being less than a dopant concentration of the source/drain regions. Accordingly, the LDD regions are formed prior to formation of the source/drain regions. In the process flow of semiconductor manufacture, the LDD regions are formed prior to the formation of the dielectric spacers of the sidewalls of the patterned stack.

In high voltage transistors, the lateral offset between the respective source/drain region and the patterned stack is considerably larger than the thickness of the dielectric spacers. Accordingly, a separate mask is used to define the lateral offset, that is, the source/drain-to-channel distance. Accordingly, the LDD regions extend beyond the thickness of the spacers to portions of the main surface of the substrate uncovered with the spacers and the patterned stack. This offset in high voltage transistors can be 500 nm on each side of the patterned stack. Such a large lateral offset in particular serves to reduce GIDL currents (gate induced drain leakage). Due to the large voltage applied to the drain, in the off-state of a high voltage transistor, band-to-band tunnelling may otherwise occur (arising from distorted electronic band structures in the region of the drain that is overlapped by the gate). The large lateral offset between the source/drain regions (at least of the drain region) relative to the patterned gate stack helps to lower the electric field arriving at the gate-drain-overlap region in the off-state, thus reducing distortion of the electronic band structure.

On the other hand such large lateral offsets are disadvantageous since they consume large amounts of substrate surface area.

DE 101 200 52 A1 discloses a semiconductor product having a transistor comprising drift zones formed in substrate material around trenches etched into the substrate. After forming the source/drain regions first, the trenches are etched on opposed sides of each source/drain region. Dopants are then implanted into bottom surfaces and sidewalls of the trenches and the trenches are filled with a dielectric. Accordingly, each source/drain region is connected to two opposed buried drift zones. One drift zone of each respective source/drain region is connected to the channel region, which is defined by subsequent deposition of the gate stack between the two source/drain regions.

DE 101 200 52 A1 accordingly achieves reduction of the lateral offset between the source/drain regions and the gate stack to some degree. However, the temporal order of steps in the process flow is rather incompatible with the usual process flow starting with gate stack formation prior to formation of the source/drain regions. Furthermore, additional steps are required for filling the trenches and planarizing the substrate surface in order to allow subsequent gate stack formation.

### SUMMARY OF THE INVENTION

In one aspect, the present invention provides a semiconductor product with reduced substrate surface area required per transistor and producible with decreased cost and effort. In a further aspect, the present invention provides a method for forming a semiconductor product, comprising an integrated transistor requiring less substrate surface area, without the need to reduce its operating voltage.

According to embodiments of the invention, a semiconductor product includes a substrate and an integrated transistor. The integrated transistor includes a patterned stack at least including a gate dielectric arranged on the substrate and a gate electrode arranged on the gate dielectric. A first and a second source/drain region are implanted in the substrate. The substrate includes recesses disposed on opposed sides of the patterned stack. Each recess has a bottom surface arranged at a depth below the gate dielectric. The first and second source/drain region are arranged in a substrate region adjacent to the bottom surfaces of the recesses.

According to embodiments of the invention, a semiconductor product is provided that includes a substrate surface being recessed (e.g., comprising a recess, trench or cavity, respectively) in those surface areas where the source/drain regions are formed. Whereas in conventional integrated transistors the substrate surface at the source/drain regions and the substrate surface covered with the patterned stack are on the same vertical position in direction perpendicular to the overall main surface of the substrate. According to embodiments of the invention, the local substrate surface at the source/drain regions is at a lower vertical position than the patterned stack. Thereby a vertical offset between the source/drain regions and the patterned stack is achieved which, in addition to the lateral offset, increases the path length between the channel region and the respective source/drain electrode. The recesses in the substrate are located at the same lateral positions at which the source/drain regions are formed. Therefore, the recesses may be formed easily by continuing etching directly after patterning the gate stack (formed of the gate dielectric layer and the gate electrode layer) without the need to provide additional process steps (except for etching the recesses themselves). The recesses are formed between the patterned stack and the insulating trench filling, thereby shaping the lateral cross-section of the recesses. Afterwards, conventional process steps may be performed to form the spacers and to form the source/drain regions at the bottom surfaces of the recesses. Furthermore, no change of the way of performing dopant implantation for source/drain region formation is required since the implantation depth need not be changed. Instead, only the local height of the substrate surface is lower than the height of the overall main surface of the substrate. The implantation depth is not influenced thereby.

Preferably the substrate has a main surface, the gate dielectric being arranged on the main surface of the substrate and the bottom surfaces of the recesses being arranged at a depth below the main surface.

The semiconductor product according to embodiments of the invention preferably comprises a ridge being formed of substrate material and comprising sidewalls, wherein the bottom surfaces of the recesses are abutting on the sidewalls of the recesses. Since the patterned stack is used for patterning the semiconductor substrate itself according to embodiments of the invention, the sidewalls of the ridge are also the sidewalls of the recesses.

Preferably dielectric spacers are provided on sidewalls of the patterned stack, the dielectric spacers covering the sidewalls of the ridge and extending to the bottom surfaces of the recesses. Since, according to embodiments of the invention, the recesses are formed directly adjacent to the patterned stack in a lateral direction (that is parallel to the main surface of the substrate), the spacers cover the sidewalls of the ridge of the substrate material supporting the patterned stack.

Furthermore, each dielectric spacer covers a portion of the bottom surface of the respective recess. The width of the portion covered by the respective spacer corresponds to the thickness of the spacer in a lateral direction.

Preferably lightly doped diffusion regions are provided, for instance as a result of implantation, in the sidewalls of the ridge of substrate material and in the bottom surfaces of the recesses. The dopant concentration of the lightly doped diffusion regions is less than the dopant concentration of the first and second source/drain region.

Preferably the first and second source/drain regions are connected to source/drain contacts extending to the bottom surfaces of the recesses. The vertical extension of the contacts is increased by the depth of the recesses compared to prior art.

Preferably the first and second source/drain regions are offset from the gate dielectric in a vertical direction perpendicular to the main surface of the substrate, a vertical offset corresponding to the depth of the recesses.

Furthermore, the first and second source/drain regions are offset from the gate dielectric in a lateral direction. However, the lateral offset may preferably correspond to the thickness of the dielectric spacers or may be larger than the thickness of the spacers but smaller than the lateral offset of conventional integrated transistors. Due to the additional vertical offset achieved according to embodiments of the invention, the lateral offset in any case is reduced compared to prior art. The lateral offset may be reduced by the amount of the vertical offset (which is defined by the depth of the recesses). Preferably, the vertical offset is between about 150 and about 250 nm.

Preferably, each of the recesses is disposed between the patterned stack and a respective insulating trench filling (shallow trench isolation; STI).

The dielectric spacers may comprise a nitride or oxide material. The substrate preferably is a semiconductor substrate like a silicon substrate and the transistor preferably is a high-voltage field effect transistor arranged in a periphery region of a memory device.

The high voltage field effect transistor may be operable at an operating voltage in the range between about 10 and about 25 volts, preferably between about 12 and about 20 volts.

The present invention also provides methods of forming a semiconductor product. In a preferred embodiment a substrate is provided. A gate dielectric layer is deposited on the substrate, and a gate electrode layer is deposited on the gate dielectric layer. The gate electrode layer and the gate dielectric layer are patterned by etching, thereby forming at least one patterned stack. The substrate is etched using the at least one patterned stack as a mask, thereby forming recesses in the substrate on opposed sides of the patterned stack. The recesses have bottom surfaces arranged in the substrate at a depth below the gate dielectric layer. Lightly doped diffusion regions are formed in the substrate, and dielectric spacers are formed on sidewalls of the patterned stack. First and second source/drain regions are then formed in the substrate by implanting a dopant in the bottom surfaces of the recesses.

According to embodiments of the invention, the substrate is etched beyond the main surface in those regions laterally adjacent to the patterned stack. Thereby, the recesses are to be formed at lateral positions where the source/drain regions will be formed later. Since substrate etching is performed subsequently to etching of the gate electrode layer and of the gate dielectric layer, only little effort and costs are required for providing the recesses. In the preferred method according to embodiments of the invention, the source/drain regions are formed at the bottom surfaces of the recesses (rather than at the main surface of the substrate).

Preferably, a ridge of substrate material is formed when the substrate is etched. The ridge includes sidewalls and the bottom surfaces of the recesses abutting to the sidewalls of the ridge.

Preferably, the lightly doped diffusion regions are formed by implanting a further dopant in the sidewalls of the ridge of substrate material and in the bottom surfaces of the recesses. Preferably, the dopant is implanted by an angled implantation using an implantation angle of between about 30 and about 60, preferably about 40 to about 50 (for instance 45) degrees relative to the normal to the main surface of the substrate. In contrast to conventional methods, also p-type dopants like boron (usually implanted vertically) are implanted by an angled implantation in order to dope the sidewalls of the ridge and those substrate regions close to these sidewalls.

Preferably, dielectric spacers extending to the bottom surfaces of the recesses are formed. The dielectric spacers cover sidewalls of the patterned stack as well as sidewalls of the ridge of substrate material. Though the way of technologically forming the spacers need not be changed as such, deeper spacers extending down to the bottom of the recesses are automatically formed due to the exposed sidewalls of the ridge.

The first and second source/drain regions can be formed by implanting the dopant in the substrate using the patterned stack and the dielectric spacers as a mask.

Preferably, subsequent to forming source/drain regions, source/drain contacts are formed by depositing a dielectric layer on the substrate comprising the transistor, and etching contact holes in the dielectric layer, thereby exposing the bottom surfaces of the recesses. The source/drain contacts can then be formed in the contact holes.

A metal silicide layer is preferably formed selectively at the bottom surfaces of the recesses by depositing cobalt (or another material) on the bottom surfaces of the recesses and on the gate electrode (or at least on a portion of an upper surface of the wordline to be contacted) and by subsequently forming cobalt silicide by means of a temperature heating step. As the gate electrode is protected by the silicide layer and by the dielectric spacers on its sidewalls, self-adjusted etching of contact holes (for the source/drain contacts) in the dielectric layer selectively to the silicide layer is achieved.

The above method is preferably used for forming high voltage transistors having a gate length of between about 0.6 and about 1.3 μm. The depth of the recesses preferrably is between about 150 and about 250 nm and the thickness of the dielectric spacers defining the minimum lateral offset may be in the range between about 50 and about 150 nm. Accordingly, the lateral offset may be reduced from a conventional amount of offset down to the thickness of the spacers, which may be chosen to be rather low.

In other embodiments, the present invention provides an integrated memory device including a substrate, a memory array arranged on the substrate and a periphery region for operating and accessing the memory array, wherein the periphery region comprises an integrated transistor as described herein above. The memory device may be a flash memory device or an embedded flash memory device, the memory array comprising one-volatile memory cells like NROM cells (nitride read-only memory) or floating gate transistor cells.

### BRIEF DESCRIPTION OF THE DRAWINGS

Hereinbelow the invention is described with reference to the accompanying figures.

FIG. 1 is a cross-sectional view of a semiconductor product according to prior art;

FIG. 2 is a cross-sectional view of a semiconductor product according to an embodiment of the present invention;

FIG. 3 is an enlarged cross-sectional view of FIG. 2;

FIG. 4 is a top view of a memory device according to an embodiment of the present invention; and

FIGS. 5 to 14 are cross-sectional views of a semiconductor product during various steps of a method according to the invention.

The following list of reference symbols can be used in conjunction with the figures:

| | |
|---|---|
| 1 | Transistor |
| 2 | Substrate |
| 3 | Patterned stack |
| 4 | Gate dielectric |
| 4a | Gate dielectric layer |
| 5 | Gate electrode |
| 5a | Gate electrode layer |
| 7 | Dielectric spacer |
| 8 | Insulating trench filling |
| 9 | Ridge |
| 10 | Lightly doped diffusion region |
| 11 | First source/drain region |
| 12 | Second source/drain region |
| 13 | Sidewall of patterned stack |
| 14, 15 | Dopant |
| 16 | channel stop diffusion region |
| 17 | Metal-silicide layer |
| 19 | Sidewall of ridge |
| 20 | Source/drain contact |
| 21 | Dielectric layer |
| 22 | Main surface |
| 23 | Contact hole |
| 25 | Semiconductor product |
| 27 | Portion of bottom surface |
| 28 | Lateral offset |
| 29 | Vertical offset |
| 30 | Memory device |
| 31 | Periphery region |
| 32 | Memory array |
| 33 | Memory cell |
| B | Bottom surface |
| d | Depth |
| n | Dopant concentration |
| R | Recess |
| S | Side |
| t | Thickness |
| x, y | Directions |

### DETAILED DESCRIPTION OF ILLUSTRATIVE EMBODIMENTS

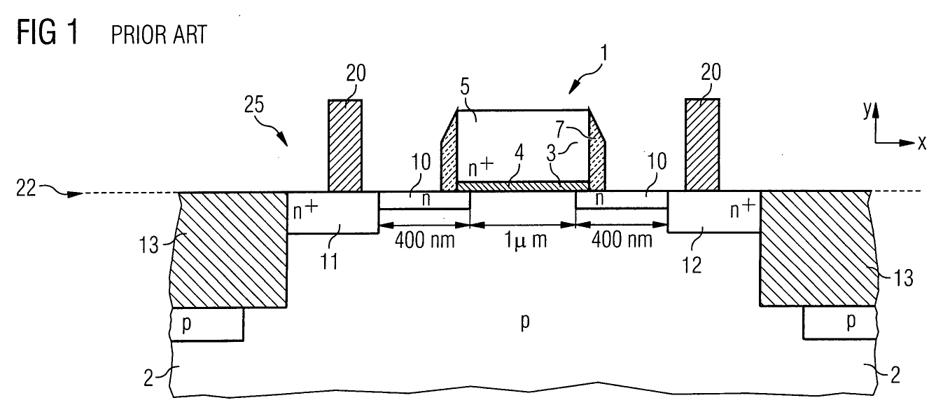

FIG. 1 illustrates a cross-sectional view of a semiconductor product according to prior art. The semiconductor product 25 comprises a transistor 1 integrated in a semiconductor substrate 2. The substrate 2 may be a p-doped substrate or may comprise a p-doped well in a substrate region in which the transistor is formed. On opposed sides of the transistor 1 insulating trench fillings 8 (shallow trench isolations; STI) are formed. Below the insulating trench fillings, channel stop diffusion regions 16 may be provided in order to prevent parasitic transistors. Alternatively, deep insulating trench fillings (deep trench isolation; DTI) may be provided.

On a main plane 22 of the substrate 2 a patterned stack 3 comprising a gate dielectric 4 and a gate electrode 5 (forming part of a wordline) are formed. On opposed sidewalls of the patterned stack 3, dielectric spacers 7 (preferably comprising a nitride) are formed. Below the planar main surface 22 of the substrate 2 (the main surface at least being planar in the area of the transistor 1) source/drain regions 11, 12 (HDD regions; highly doped drain regions) as well as lightly doped diffusion regions 10 (LDD regions, lightly doped drain regions) are provided. The first source/drain region 11 and the second source/drain region 12 are allocated rather distant from the patterned stack 3. For each of the source/drain regions 11, 12 the lateral offset is about 400 nm, thereby consuming additional substrate surface area, which is disadvantageous. The transistor 1 for instance is a high voltage transistor to be operated at a voltage between 17 and 18 volts and having a gate length of the gate electrode 5 of about 1 μm. Though an n-type transistor is illustrated in FIG. 1, alternatively a p-type transistor is constructed as illustrated in FIG. 1 (by reversing the dopant types). Source/drain contacts 20 of a metal or a metal alloy are contacting the source/drain regions.

The large lateral offset of the high voltage transistor 1 is required due to the need to prevent or to at least reduce gate induced drain leakage currents occurring in the off-state of the transistor.

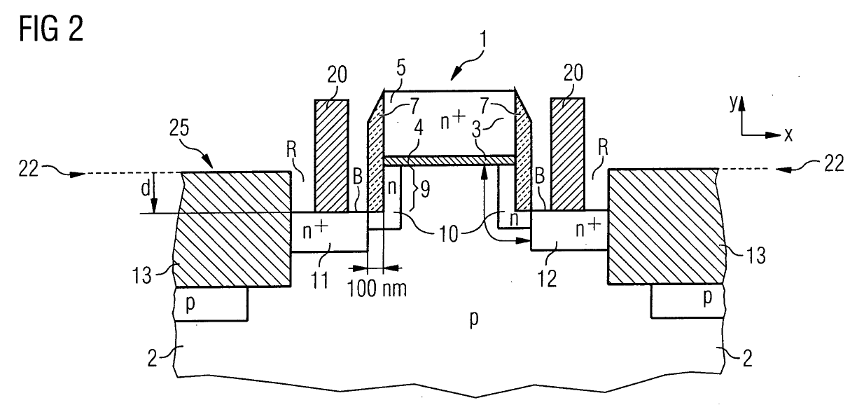

FIG. 2 illustrates a semiconductor product 25 according to a first embodiment the invention comprising a transistor 1 having recesses R with bottom surfaces B arranged deeper than the main surface 22 of the substrate 2. The recesses R preferably have been formed subsequent to patterning the gate electrode 5 and the gate dielectric 4. The recesses R comprise bottom surfaces B that, in a lateral direction x, extend to the lateral positions of the sidewalls of the patterned stack 3. Due to the presence of the recesses R, a ridge 9 of substrate material is formed between the two recesses R. The ridge 9 comprises sidewalls covered with the dielectric spacers 7. Accordingly, the dielectric spacers 7 extend down to the bottom surfaces B of the recesses R. Due to the depth d of the recesses R, an additional vertical offset between the source/drain regions 11, 12 and the gate dielectric 4 is achieved. As a consequence, the lateral offset may be reduced. The minimum lateral offset required is defined by the thickness of the dielectric spacers 7, which in FIG. 2 is, for instance, 100 nm. The sum of the lateral and vertical offsets corresponds to the total offset or path length between the channel region and the respective source/drain region 11, 12 as indicated by the double-headed arrow.

Due to the recesses R and the ridge 9 formed therebetween, the lightly doped diffusion regions 10 extend along the sidewalls of the patterned stack 3 and of the ridge 9 as well. They may be formed by angled implantation of dopants into the sidewalls of the ridge 9. The source/drain contacts 20 extend down to the bottom surfaces B of the recesses R. Though FIG. 2 illustrates an n-type transistor, it is to be noted that embodiments of the invention also refer to p-type transistors for which all dopant regions in FIG. 2 are to be reversed from n to p and vice versa.

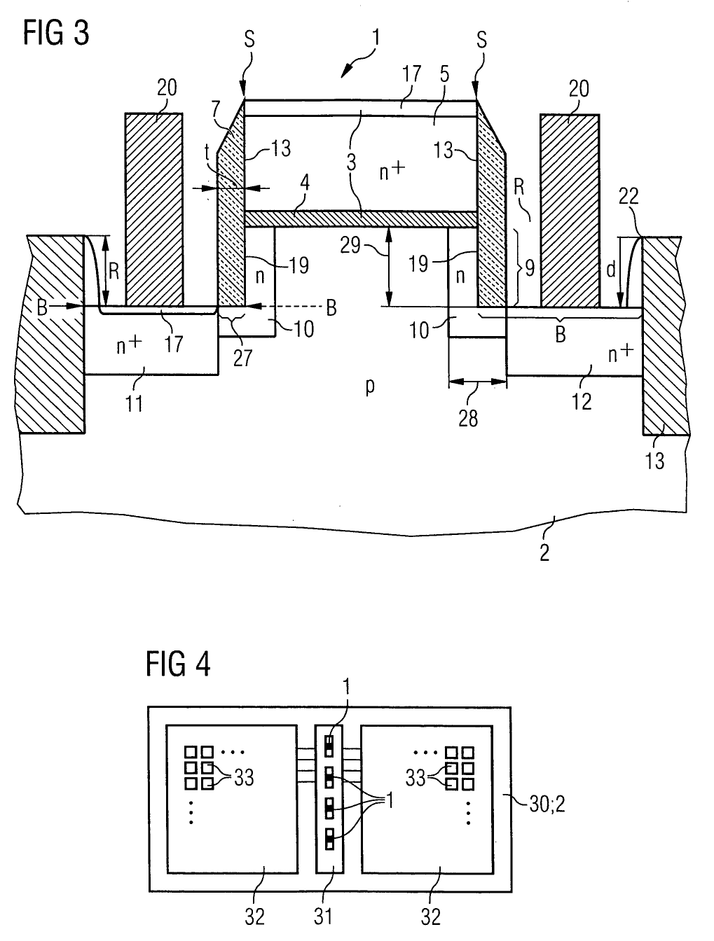

FIG. 3 is an enlarged cross-sectional view of FIG. 2. The enlarged cross-sectional view illustrates in a more detailed manner the ridge 9 formed between the recesses R. The ridge 9 comprises sidewalls 19 flushing with sidewalls 13 of the patterned stack 3. These sidewalls 13, 19 are arranged at opposed sides S of the patterned stack 3. Both the sidewalls 13 and the sidewalls 19 are covered with the dielectric spacers 7 which, according to embodiments of the present invention, extend down to the bottom surfaces B of the recesses R. The thickness t of the dielectric spacers 7 corresponds to the minimum lateral offset 28 and further corresponds to the portion 27 of the bottom surfaces B covered with the dielectric spacers 7. The remaining portions of the bottom surfaces B are exposed when implanting dopants for forming a first 11 and a second source/drain region 12 in the substrate. The depth d of the recesses R corresponds to the height of the ridge 9 and further corresponds to the vertical offset 29. Embodiments of the present invention allow reduction of the lateral offset 28 by an extent corresponding to the amount of the vertical offset 29. The vertical offset 29 is the vertical distance or depth d between the main surface 22 of the substrate 2 and the bottom surfaces B of the recesses R. At the interface surfaces between the source/drain regions 11, 12 and the source/drain contacts 20, metal-silicide layers 17 are formed, as illustrated on the left side in FIG. 3. It is to be noted that also on the right side the metal-silicide layer (not illustrated) is formed.

FIG. 4 illustrates a top view of a memory device according to embodiments of the present invention. The memory device 30 comprises a substrate 2, a memory array 32 arranged on the substrate and a periphery region 31 for operating and accessing the memory array 32. The periphery region 31 comprises at least one integrated transistor 1 of the same kind as illustrated in FIGS. 2 and 3 in cross-sectional view. These transistors provided in the periphery region 31 are high-voltage transistors to be operated at operating voltages of between about 10 and about 25 volts, for instance between about 17 and about 18 volts. Accordingly, such transistors according to prior art would require an additional margin of lateral offset as illustrated in FIG. 1 in order to prevent gate-induced drain leakage currents (GIDL). According to embodiments of the invention, however, the lateral offset may be reduced to the thickness t of the dielectric spacers 7 (FIG. 3).

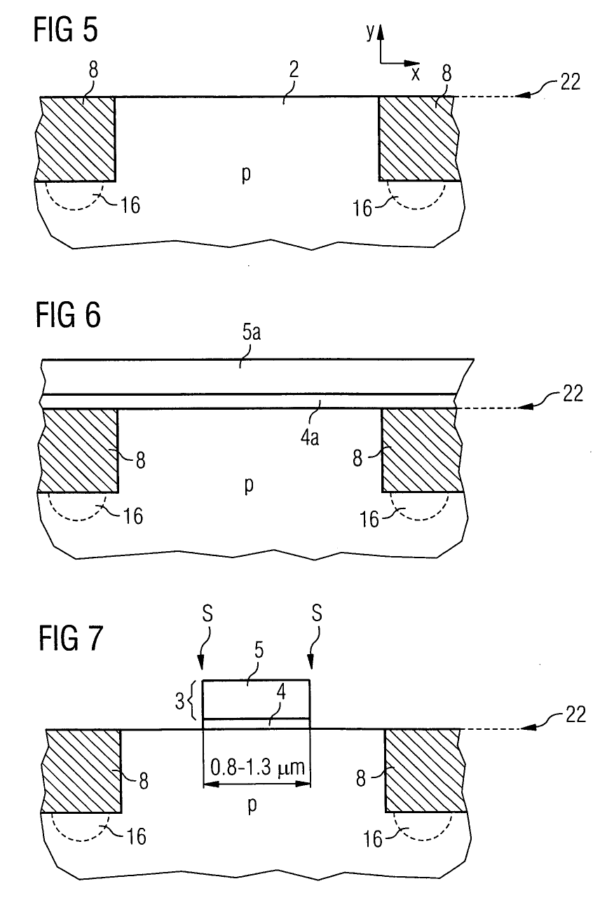

FIGS. 5 to 14 illustrate a method according to embodiments of the present invention for forming a semiconductor product. The semiconductor product formed according to this method will have a transistor comprising source/drain regions being arranged in the substrate below (and adjacent to) bottom surfaces of recesses etched into the substrate.

According to FIG. 5, a substrate 2, preferably a semiconductor substrate like a silicon substrate, is provided and insulating trench fillings 8 are formed in the substrate 2 by first forming trenches in the substrate and subsequently filling the trenches with dielectric material like an oxide. Filling the trenches with the dielectric material is performed by depositing the dielectric material on the substrate such that the trenches are completely filled and the surface around the trenches is covered with the dielectric material that subsequently is planarized by chemical-mechanical polishing.

The substrate 2, for instance, is a p-doped substrate or an n-doped substrate. The substrate can comprise a p-doped or an n-doped well. In FIG. 5 “p” denotes a p-doped substrate region in an area in which a transistor is to be formed. Embodiments of the invention, however, also apply formation of n-type as well as p-type transistors.

Channel stop diffusion regions 16 may be formed prior or subsequent to formation of insulating trench fillings by implanting a dopant of the same dopant type p as the doped substrate region through a mask. In a p-doped substrate region in which an n-type transistor is to be formed, the channel stop diffusion region 16 comprises p-dopants of increased dopant concentration p⁺ compared to the substrate region. The channel stop diffusion region 16 serves to prevent the occurrence of parasitic currents between integrated transistors or other microelectronic devices arranged close to one other on the substrate 2.

The substrate 2 comprises a main surface 22 defining lateral directions x and a vertical normal direction y.

According to FIG. 6, a gate dielectric layer 4a and a gate electrode layer 5a are deposited on the substrate 2 in sequence for forming a plurality of patterned stacks to be used as gate stacks for integrated MOSFET transistors (metal oxide semiconductor field effect transistors).

According to FIG. 7, the stack of layers comprising the gate dielectric layer 4a and the gate electrode layer 5a is patterned by forming a patterned mask thereon, lithographically exposing the stack of layers and etching the stack of layers using a mask (not illustrated in the figures) thereby forming a patterned stack 3 comprising a gate dielectric 4 and a gate electrode 5. The width in the lateral direction x preferably is between about 0.6 and about 1.3 μm since the integrated transistor to be formed as a high voltage transistor operable at an operating voltage of between about 10 and about 25 volts, preferably about 12 to about 20 volts.

The patterned stack 3 is arranged on the main surface 22 of the substrate 2. In the lateral direction x the patterned stack 3 is arranged in the center of a substrate region confined by two insulating trench fillings 8. The patterned stack 3 comprises two sides S opposed to one another and defining a gate length of the integrated transistor to be formed.

A conventional process flow would then proceed, after FIG. 7, with LDD implantation, spacer formation and source/drain region formation and would be performed similarly as according to FIGS. 9, 10, 11, etc. In a conventional method, etching of the gate dielectric layer 4a (FIG. 6), therefore, is stopped before the complete thickness of the gate dielectric layer 4a. Accordingly, in a conventional process, the gate dielectric 4 would also be present on those areas of the substrate surface being exposed in FIG. 7.

According to the invention, however, the gate dielectric 4 is completely removed from those areas of the substrate surface arranged between the lateral ends of the patterned stack 3 and the lateral ends of the insulating trench fillings 8.

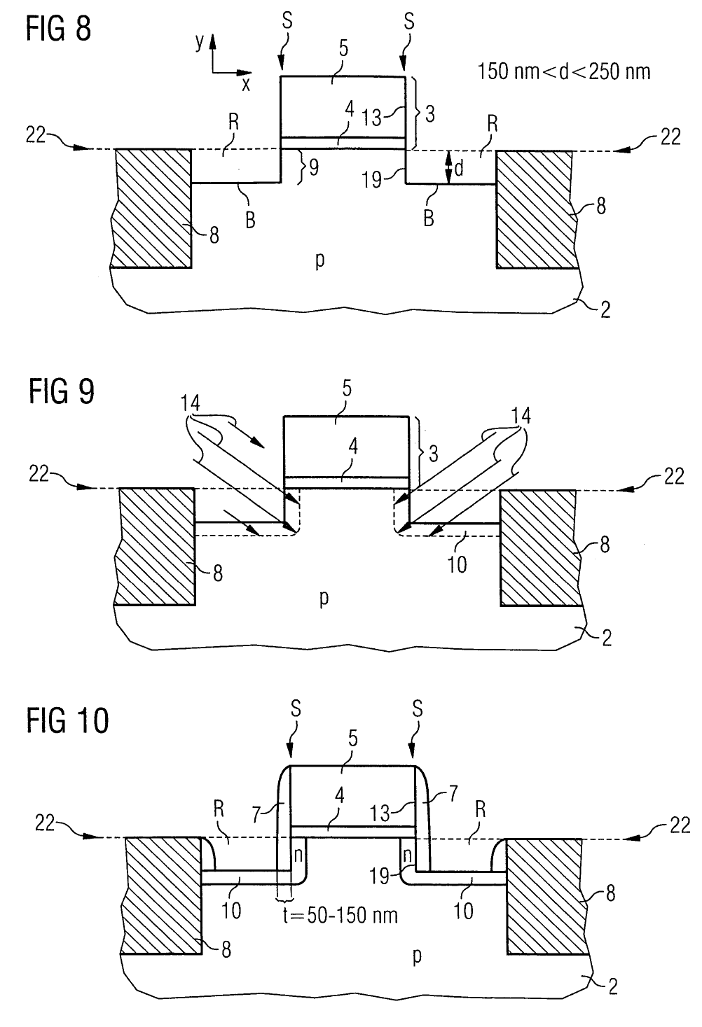

According to the present invention, recesses R are etched into the substrate 2 as illustrated in FIG. 8. Etching of the recesses R may be performed by continuing etching in a same etching chamber already used for forming the patterned stack 3. Alternatively, another etching chamber may be used for etching the recesses R into the substrate 2. In either case it is a benefit of the invention that no lithographic patterning is required for etching the recesses R into the substrate 2 since the patterned stack 3 as well as the insulating trench fillings 8 serve as a mask and thus self-adjusted etching of the recesses R relative to the patterned stack 3 is automatically achieved. Etching of the substrate 2 to form the recesses R is started with recessing the main surface 22 of the substrate 2 in those surface portions arranged between sidewalls 13 of the patterned stack and the insulating trench fillings 8. As the recesses R are etched on two opposed sides S of the patterned stack 3, a ridge 9 is formed in between the recesses R. Thereby, sidewalls 19 of the ridge 9 are formed and bottom surfaces B of the recesses R arranged at a depth d below the main surface 22 (in normal direction y of the main surface 22) are formed. The sidewalls 19 of the ridge 9 of substrate material are flush with the sidewalls 13 of the patterned stack 3 since the patterned stack 3 is used for self-adjusted etching of the recesses R. The sidewalls 19 of the ridge 9 are also the sidewalls of the recesses R. The bottom surfaces B of the recesses R are abutting to the sidewalls 19. The upper sidewall of the insulating trench filling 8 (shallow trench isolation; STI) is elevated relative to the bottom surfaces B of the adjacent recesses R; the difference in vertical position y corresponding to the depth d of the recesses R.

According to FIG. 9, lightly doped diffusion regions 10 are formed by implanting a dopant 14 into the sidewalls 19 of the ridge 9 and into the bottom surfaces B of the recesses R. Implantation of the dopants 14 preferably is performed by an angled implantation, preferably using the quad-mode in order to implant the dopants 14 through the sidewalls 19 into the ridge 9 of substrate material. A sidewall oxide can be formed on the sidewalls of the patterned stack prior to implanting dopants for the LDD regions. Thereby, the sidewalls of the patterned stack are passivated.

According to FIG. 10, dielectric spacers 7 are then formed on the opposed lateral ends S of the patterned stack 3 thereby covering sidewalls of the patterned stack 3. Formation of the dielectric spacers 7 is performed in conventional manner by first depositing a thin conformal layer of dielectric material like a nitride, an oxide or an oxinitride and by second anisotropically etching the layer in a direction perpendicular to the main surface 22 of the substrate.

According to embodiments of the invention, however, the presence of the recesses R results in formation of spacers 7 extending to the bottom surfaces B of the recesses R, the spacers 7 arranged on the sidewalls 13 of the patterned stack 3 also covering the sidewalls 19 of the ridge 9. Further electric spacers are formed on those portions of the insulating trench filling 8 being exposed by the recesses. However, these spacers are smaller in vertical extension than the spacers arranged on the sidewalls 13, 19 of the patterned stack 3 and of the ridge 9 of substrate material.

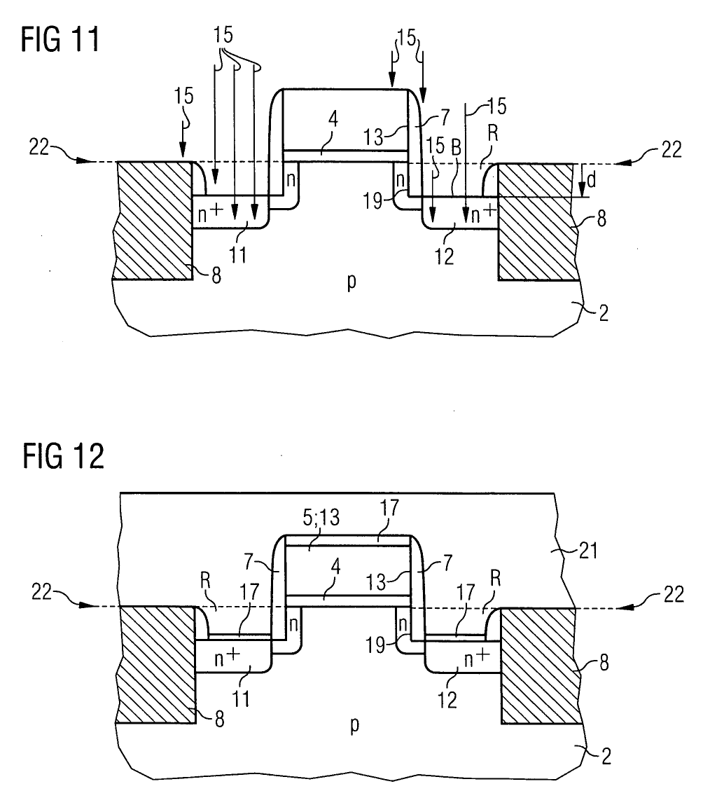

According to FIG. 11 source/drain regions 11, 12 are formed by implanting a dopant 15 thereby accumulating a high dopant concentration n⁺ in substrate regions below and adjacent to those portions of the bottom surfaces B of the recesses R being exposed between the dielectric spacers. As illustrated in FIG. 10, at the bottom surfaces B of the recesses R the dielectric spacers 7 covering the sidewalls 19 of the ridge have a thickness t. The thickness t may preferably be between about 50 and about 150 nm. This thickness of the dielectric spacers 7 at the bottom surfaces B defines a lateral offset 28 (FIG. 3) of the first and second source/drain regions 11, 12 relative to the sidewalls 19 of the ridge 9 and the sidewalls 13 of the patterned stack 3. Whereas according to FIG. 1 the lateral offset of typically 400 nm is much larger than the thickness of dielectric spacers, according to embodiments of the present invention the lateral offset may be reduced significantly (to the thickness t of the dielectric spacers 7 at maximum) since, according to embodiments of the invention, an additional vertical offset 29 is provided due to the formation of the recesses R. According to embodiments of the invention, the lateral offset 28 may be reduced (compared to prior art integrated transistors) to an extent corresponding to the vertical offset 29, that is corresponding to the depth d of the recesses R. The deeper the recess R, the larger the vertical offset 29 and the smaller the minimum lateral offset 28 required for avoiding GIDL currents in the off-state of the high voltage transistor.

According to FIG. 12, a silicide layer, preferably of cobalt silicide, has been formed in a self-aligned manner selectively on exposed portions of the bottom surfaces of the recesses (where silicon is exposed) and on an exposed portion of the upper surface of a wordline (where polysilicon is exposed). Alternatively, the silicide layer can be formed prior to implanting the source/drain dopants into the substrate. Subsequent to implanting and silicide formation, a dielectric layer 21 is deposited on the substrate 2 including the transistor in order to reduce topography for a subsequent source/drain contact formation and wiring deposition.

The silicide layer, preferably made of cobalt silicide, is formed on the exposed surfaces of the source/drain regions and on the exposed portion of an upper surface of the wordline. The silicide layer 17 is formed in a self-aligned manner by depositing cobalt and applying a heating step, thereby forming cobalt silicide on the polysilicon of the gate electrode 5 and on the source/drain regions 11, 12. The silicide layer serves as an etch stop layer.

Due to the fact that the LDD regions are completely covered with the spacers 7, no silicide layer is formed on the LDD regions; self-aligned formation (salicide; self-aligned silicide) selectively to the LDD region surfaces automatically being achieved according to embodiments of the invention. In a prior art process, however, only a small portion of the LDD regions would be covered with the dielectric spacers since conventional LDD regions provide a comparatively larger lateral offset whereas there is no vertical offset between the source/drain regions and the patterned stack. Accordingly, in a conventional process no self-aligned silicidation selectively to the surface of LDD regions would be achieved since also the substrate silicon in the LDD regions uncovered with the spacers would be silicided, this silicide providing a conductive path between the source/drain regions and the patterned stack incompatible with the purpose of the LDD regions. Accordingly, precise lithographic patterning steps are required in prior art processes in order to adjust a mask enabling silicidation of the source/drain regions (and of the gate electrode) but preventing silicidation of the LDD regions.

The dielectric layer 21 deposited subsequently has a thickness sufficiently large to cover the top side of the patterned stack 3 and to achieve reduction of topography by subsequently chemically-mechanically polishing the upper surface of the dielectric layer 21.

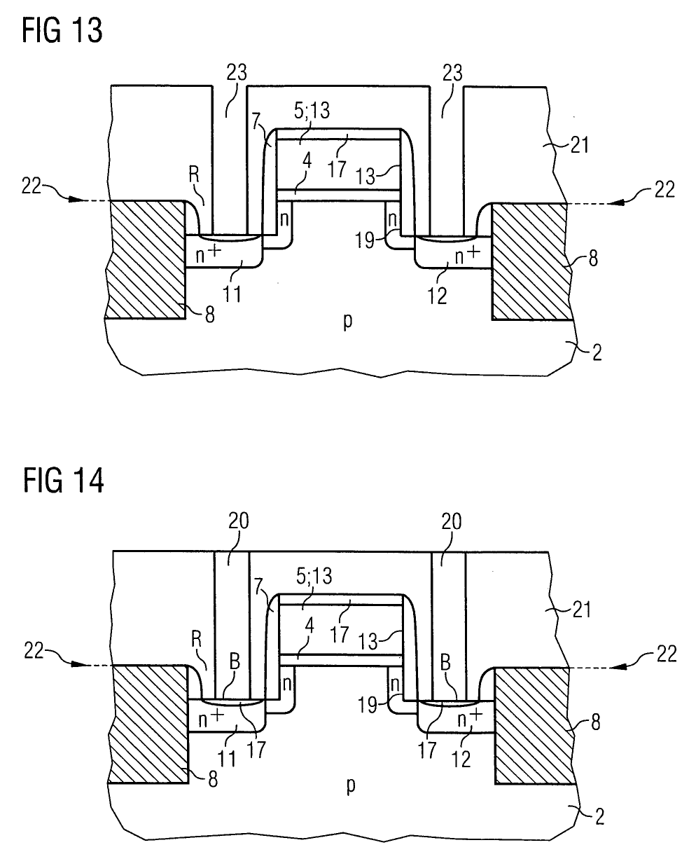

According to FIG. 13 contact holes 23 are etched into the dielectric layer 21 thereby exposing portions of the bottom surfaces B of the recesses R. Thereby, the first and second source/drain regions 11, 12 and a portion of an upper surface of the wordline to be contacted are exposed.

Subsequently, a conductive material is deposited filling the contact holes 23 and covering the upper surface of the dielectric layer 21, the conductive material then being removed from the upper surface of the dielectric layer 21 by etching or polishing. Thereby, source/drain contacts 20 are formed in the dielectric layer 21 for contacting the first and second source/drain regions 11, 12. Etching is performed selectively to the cobalt silicide.

By the above-described method, an n-type MOSFET transistor is formed providing a vertical offset of the n-doped source/drain regions relative to the gate dielectric. However, the invention also applies to the formation of p-type MOSFET transistors having a vertical offset of the source/drain regions relative to the gate dielectric. In this case the polarity of the dopant type of the respective diffusion regions and structural elements of the transistor are to be reversed in FIGS. 5 to 14.

The vertical offset allows reduction of the lateral offset between the source/drain regions and the patterned gate stack. Thereby the substrate surface required per transistor is significantly reduced. For instance, the lateral offset for a high voltage transistor may be reduced by about 20 to 40% of the substrate area required for a conventional transistor. The depth of the recesses may preferably be in the range between about 150 and about 250 nm, for instance about 200 nm. Maximum reduction of the lateral offset is achieved if the lateral offset is defined by the thickness of the dielectric spacers covering the sidewalls of the patterned stack and of the ridge of substrate material. With the source/drain regions arranged deeper in the substrate relative to the main surface of the substrate, the voltage at which breakdown of the transistor occurs is higher than in the case where the recesses are absent.

The depth of the insulating trench fillings (shallow trench isolation; STI) may be chosen larger than in prior art to compensate for the smaller distance between the source/drain regions and the bottom side of the insulating trench fillings. Furthermore, deep isolation trenches (DTI) may be formed rather than shallow trench isolations, thereby removing the need to form channel stop implants.

Embodiments of the present invention in particular may be used to form flash memory products and embedded flash memory products comprising at least one memory array and a periphery region for controlling and accessing the memory arrays; the improved transistor with vertically offset source/drain regions being provided in the periphery region and being operable at high operating voltages of preferably between about 12 and about 25 volts or even above about 25 volts without the risk of breakdown of the transistor in the off-state.

What is claimed is:

1. A semiconductor product comprising a substrate and an integrated transistor, the integrated transistor comprising:
a patterned stack at least comprising a gate dielectric arranged over the substrate and a gate electrode arranged over the gate dielectric;
recesses disposed on opposed sides of the patterned stack, each recess having a bottom surface arranged at a depth below the gate dielectric; and
a first source/drain region and a second source/drain region arranged in the substrate, wherein the first source/drain region and second source/drain region are arranged in a substrate region adjacent to the bottom surfaces of the recesses.

2. The semiconductor product of claim 1, wherein the substrate has a main surface, the gate dielectric being arranged on the main surface of the substrate, and wherein the bottom surfaces of the recesses are arranged in the substrate at a depth below the main surface of the substrate.

3. The semiconductor product of claim 1, wherein the patterned stack further comprises a ridge being formed of substrate material and comprising sidewalls, wherein the bottom surfaces of the recesses are abutting the sidewalls of the ridge.

4. The semiconductor product of claim 3, further comprising dielectric spacers arranged on sidewalls of the patterned stack, the dielectric spacers covering the sidewalls of the ridge of substrate material and extending to the bottom surface of the respective recess.

5. The semiconductor product of claim 4, wherein each dielectric spacer covers a portion of the bottom surface of the respective recess.

6. The semiconductor product of claim 3, further comprising doped diffusion regions disposed in the sidewalls of the ridge of substrate material, the lightly doped diffusion regions having a dopant concentration being less than a dopant concentration of the first and second source/drain regions.

7. The semiconductor product of claim 1, wherein the first source/drain region and the second source/drain region are contacted by source/drain contacts extending to the bottom surfaces of the recesses.

8. The semiconductor product of claim 1, wherein the first source/drain region and the second source/drain region are offset from the gate dielectric in a vertical direction, a vertical offset corresponding to a depth of the recesses.

9. The semiconductor product of claim 8, further comprising dielectric spacers arranged on sidewalls of the patterned stack and along a sidewall of each recess, wherein the first source/drain region and the second source/drain region are offset from the gate dielectric in a lateral direction, by a lateral offset corresponding to a thickness of the dielectric spacers.

10. The semiconductor product of claim 8, wherein the vertical offset is between about 150 and about 250 nm.

11. The semiconductor product of claim 1, wherein each recess is disposed between the patterned stack and an insulating trench filling.

12. The semiconductor product of claim 1, wherein the patterned stack further comprises a silicide layer disposed on the gate electrode.

13. The semiconductor product of claim 1, further comprising dielectric spacers arranged on sidewalls of the patterned stack and along a sidewall of each recess, wherein the dielectric spacers comprise a nitride or oxide material.

14. The semiconductor product of claim 1, wherein the semiconductor product comprises a memory device comprising a periphery region, wherein the substrate comprises a semiconductor substrate and wherein the transistor comprises a high voltage field effect transistor arranged in the periphery region of the memory device.

15. The semiconductor product of claim 14, wherein the high voltage field effect transistor is operable at an operating voltage in the range between about 10 and about 25 volts.

16. A method of forming a semiconductor product comprising an integrated transistor on a substrate, the method comprising:
a) providing a substrate;
b) depositing a gate dielectric layer over the substrate;
c) depositing a gate electrode layer over the gate dielectric layer;
d) patterning the gate electrode layer and the gate dielectric layer by etching, thereby forming at least one patterned stack;
e) etching the substrate using the at least one patterned stack as a mask, thereby forming recesses in the substrate on opposed sides of the patterned stack, the recesses having bottom surfaces arranged at a depth below the gate dielectric layer;
f) forming lightly doped diffusion regions in the substrate;
g) forming dielectric spacers on sidewalls of the patterned stack; and
h) forming first and second source/drain regions in the substrate by implanting a dopant in the bottom surfaces of the recesses.

17. The method of claim 16, wherein a ridge of substrate material is formed in step e), the ridge comprising sidewalls, wherein the bottom surfaces of the recesses are abutting the sidewalls of the ridge.

18. The method of claim 17, wherein in step f) the lightly doped diffusion regions are formed by implanting a dopant in the sidewalls of the ridge of substrate material.

19. The method of claim 18, wherein in step f) the dopant is implanted in the sidewalls of the ridge of substrate material by means of an angled implantation.

20. The method of claim 17, wherein forming dielectric spacers comprises forming dielectric spacers that extend to the bottom surfaces of the recesses, the dielectric spacers covering sidewalls of the patterned stack including sidewalls of the ridge of substrate material.

21. The method of claim 16, wherein the first and second source/drain regions are formed by implanting the dopant in the substrate using the patterned stack and the dielectric spacers as a mask.

22. The method of claim 16, wherein after step h), source/drain contacts are formed by
i) depositing a dielectric layer on the substrate comprising the transistor;
j) etching contact holes in the dielectric layer, thereby exposing the bottom surfaces of the recesses; and
k) forming the source/drain contacts in the contact holes.

23. The method of claim 22, wherein beween steps h) and i) a metal silicide layer is selectively formed at exposed regions of the bottom surfaces of the recesses and at exposed regions of the gate electrode.

24. The method of claim 16, wherein etching the substrate comprises forming recesses having a depth of between about 150 and about 250 nm.

25. The method of claim 16, further comprising forming insulating trench fillings in the substrate prior to step b).

26. The method of claim 16, wherein patterning the gate electrode layer and the gate dielectric layer comprises forming a patterned stack having a gate length of between about 0.8 and about 1.3 μm.

27. The method of claim 16, wherein forming dielectric spacers comprises forming spacers having a thickness of between about 50 and about 150 nm, the thickness of the dielectric spacers defining a lateral offset of the first source/drain region and the second source/drain region from the patterned stack.

28. A memory device comprising:
a substrate;
a memory array arranged on the substrate; and
a periphery region arranged on the substrate for operating and accessing the memory array, wherein the periphery region comprises an integrated transistor, the integrated transistor comprising:
a patterned stack at least comprising a gate dielectric arranged over the substrate and a gate electrode arranged over the gate dielectric; and
a first source/drain region and a second source/drain region arranged in the substrate,
wherein the substrate comprises recesses disposed on opposed sides of the patterned stack, each recess having a bottom surface arranged at a depth below the gate dielectric, and
wherein the first and second source/drain regions are arranged in a substrate region adjacent to the bottom surfaces of the recesses.

29. The memory device of claim 28, wherein the substrate has a main surface, the gate dielectric being arranged on the main surface of the substrate, and wherein the bottom surfaces of the recesses are arranged at a depth below the main surface of the substrate.

30. The memory device of claim 29, wherein the patterned stack further comprises a ridge being formed of substrate material and comprising sidewalls, wherein the bottom surfaces of the recesses are abutting the sidewalls of the ridge.

31. The memory device of claim 28, further comprising dielectric spacers arranged on sidewalls of the patterned stack, the dielectric spacers covering the sidewalls of the ridge of substrate material and extending to the bottom surface of the respective recess.

32. The memory device of claim 31, wherein each dielectric spacer covers a portion of the bottom surface of the respective recess.

33. The memory device of claim 28, further comprising lightly doped diffusion regions disposed in the sidewalls of the ridge of substrate material, the lightly doped diffusion regions having a dopant concentration being less than a dopant concentration of the first and second source/drain region.

34. The memory device of claim 28, wherein the first source/drain region and the second source/drain region are offset from the gate dielectric in a vertical direction, by a vertical offset corresponding to a depth of the recesses.

35. The memory device of claim 31, further comprising dielectric spacers arranged on sidewalls of the patterned stack and along a sidewall of each recess, wherein the first source/drain region and the second source/drain region are offset from the gate dielectric in a lateral direction, by a lateral offset corresponding to a thickness of the dielectric spacers.

36. The memory device of claim 34, wherein the vertical offset is between about 150 and about 250 nm.

37. The memory device of claim 28, wherein the substrate comprises a semiconductor substrate and wherein the transistor comprises a high voltage field effect transistor operable at an operating voltage in the range between about 10 and about 25 volts.

38. The memory device of claim 37, wherein the transistor is operable at an operating voltage in the range between about 12 and about 20 volts.

39. The memory device of claim 28, wherein the transistor has a gate length of between about 0.6 and about 1.3 μm.

40. The memory device of claim 28, wherein the memory device is a flash memory device or an embedded flash memory device, the memory array comprising a plurality of non-volatile memory cells.
